(19) United States
(12) Patent Application Publication
(10) Pub. No.: US 2025/0201703 A1
(43) Pub. Date: Jun. 19, 2025

(54) FABRICATION METHOD FOR FORMING HIGH VOLTAGE RESISTOR NETWORKS OVER SILICON SUBSTRATES FOR USE WITHIN MULTICHIP MODULE ASSEMBLIES

(71) Applicant: Texas Instruments Incorporated, Dallas, TX (US)

(72) Inventors: Jeffrey A. West, Dallas, TX (US); Byron Lovell Williams, Plano, TX (US); Elizabeth Stewart, Dallas, TX (US); Yoshihiro Takei, TSUKUBA-SHI IBARAKI-KEN (JP); Hiroyuki Inoue, USHIKU-SHI IBARAKI-KEN (JP)

(21) Appl. No.: 18/651,018

(22) Filed: Apr. 30, 2024

Related U.S. Application Data
(60) Provisional application No. 63/609,410, filed on Dec. 13, 2023.

(51) Int. Cl. H01L 23/522; H01L 23/00

(52) U.S. Cl. CPC H01L 23/5228; H01L 24/48; H10D 1/474; H01L 2224/48245; H01L 2924/19043

(57) ABSTRACT

An integrated circuit includes a metallization structure over a semiconductor layer and having a dielectric layer, a pad metal layer on the dielectric layer and including first and second resistor terminals, and a film resistor over the pad metal layer, a first location of the film resistor connected to the first resistor terminal by a first vertical interconnect, and a second location of the film resistor connected to the second resistor terminal by a second vertical interconnect. An integrated circuit includes a metallization structure over a semiconductor layer and having a film resistor, a first resistor terminal, a second resistor terminal that is spaced apart from the first resistor terminal, and a dielectric seal structure that encloses the film resistor, wherein the film resistor is located on a first sublayer of the dielectric seal structure, and a second sublayer of the dielectric seal structure is on the film resistor.

### CROSS-REFERENCE TO RELATED APPLICATION

This application claims priority to and benefit of U.S. Provisional Patent Application Ser. No. 63/609,410, filed on Dec. 13, 2023, and entitled “Fabrication method for forming high voltage resistor networks over silicon substrates for use within multichip module assemblies”, the contents of which is hereby fully incorporated by reference.

### BACKGROUND

Electronic devices such as integrated circuits (ICs) may have circuits and/or components in multiple voltage domains, such as low voltage logic circuitry in a low voltage domain, and communications driver, amplifier, or sensing circuits in a second, high voltage domain. Resistor divider networks can be used for low voltage circuits to sense high voltages in a single device and to prevent damaging current flow between a high voltage node and low voltage sensing circuits. Discrete resistor networks can be soldered onto a host printed circuit board (PCB) outside the IC with large spacings between the two ends of each resistor to prevent air breakdown across the resistor body. However, this is expensive and takes up significant space in the system to meet the safety requirements that prevent air breakdown.

### SUMMARY

In one aspect, an integrated circuit includes a multilevel metallization structure over a semiconductor layer, the multilevel metallization structure having a dielectric layer, a pad metal layer on the dielectric layer and including first and second resistor terminals, and a film resistor over the pad metal layer, a first location of the film resistor connected to the first resistor terminal by a first vertical interconnect, and a second location of the film resistor connected to the second resistor terminal by a second vertical interconnect.

In another aspect, an integrated circuit includes a semiconductor layer and a multilevel metallization structure over the semiconductor layer, the multilevel metallization structure having a film resistor, a first resistor terminal, a second resistor terminal that is spaced apart from the first resistor terminal, and a dielectric seal structure that encloses the film resistor, wherein the film resistor is located on a first sublayer of the dielectric seal structure, and a second sublayer of the dielectric seal structure is on the film resistor.

In a further aspect, a method includes forming a dielectric layer in a multilevel metallization structure over a semiconductor layer, forming a pad metal layer on the dielectric layer and including first and second resistor terminals, and forming a film resistor over the pad metal layer, a first location of the film resistor connected to the first resistor terminal by a first vertical interconnect, and a second location of the film resistor connected to the second resistor terminal by a second vertical interconnect.

### BRIEF DESCRIPTION OF THE DRAWINGS

FIG. 1 is a partial sectional side elevation view of a portion of an electronic device with an integrated voltage divider in a multilevel metallization structure over a semiconductor layer.

FIG. 1A is a partial sectional top view of the electronic device of FIG. 1.

FIG. 1B is a partial top view of a turnaround end portion of a serpentine thin film resistor example.

FIG. 2 is a flow diagram of a method of fabricating an electronic device.

FIGS. 3-36 are partial sectional side elevation views of the device of FIG. 1 undergoing metallization structure fabrication processing according to the method of FIG. 2.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. The example structures include layers or materials described as over or on another layer or material, which can be a layer or material directly on and contacting the other layer or material where other materials, such as impurities or artifacts or remnant materials from fabrication processing may be present between the layer or material and the other layer or material. Unless otherwise stated, “about,” “approximately,” or “substantially” preceding a value means+/−10 percent of the stated value. One or more structures, features, aspects, components, etc., may be referred to herein as first, second, third, etc., for ease of description in connection with a particular drawing, where such are not to be construed as limiting with respect to the claims. Various disclosed structures and methods of the present disclosure may be beneficially applied to an electronic devices, manufacturing, testing, and/or operating an electronic device such as an integrated circuit. While such examples may be expected to provide various improvements, no particular result is a requirement of the present disclosure unless explicitly recited in a particular claim.

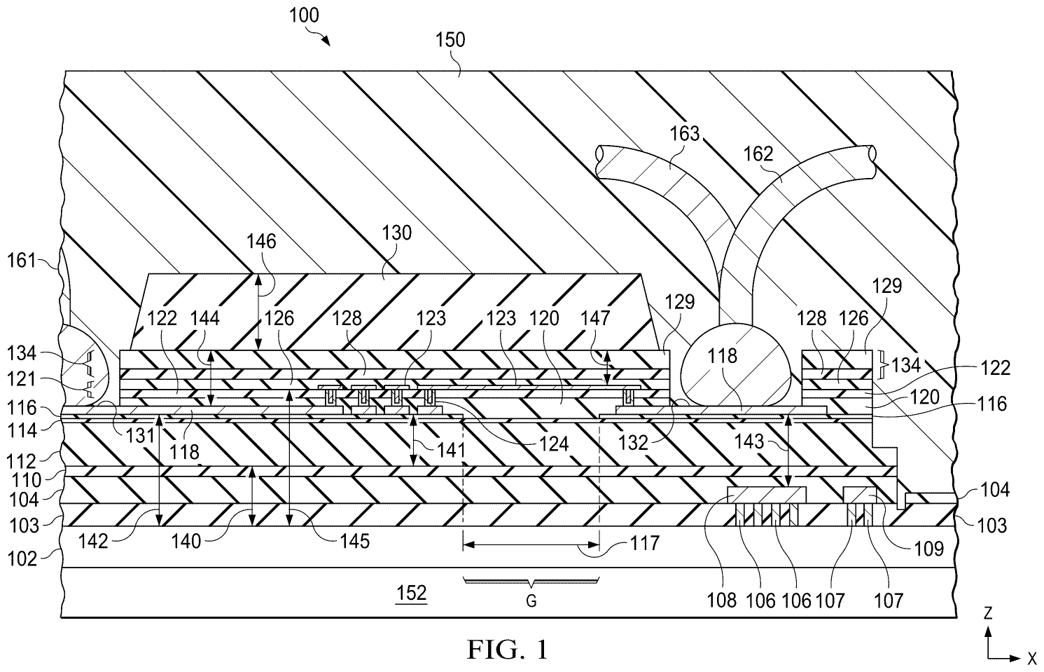

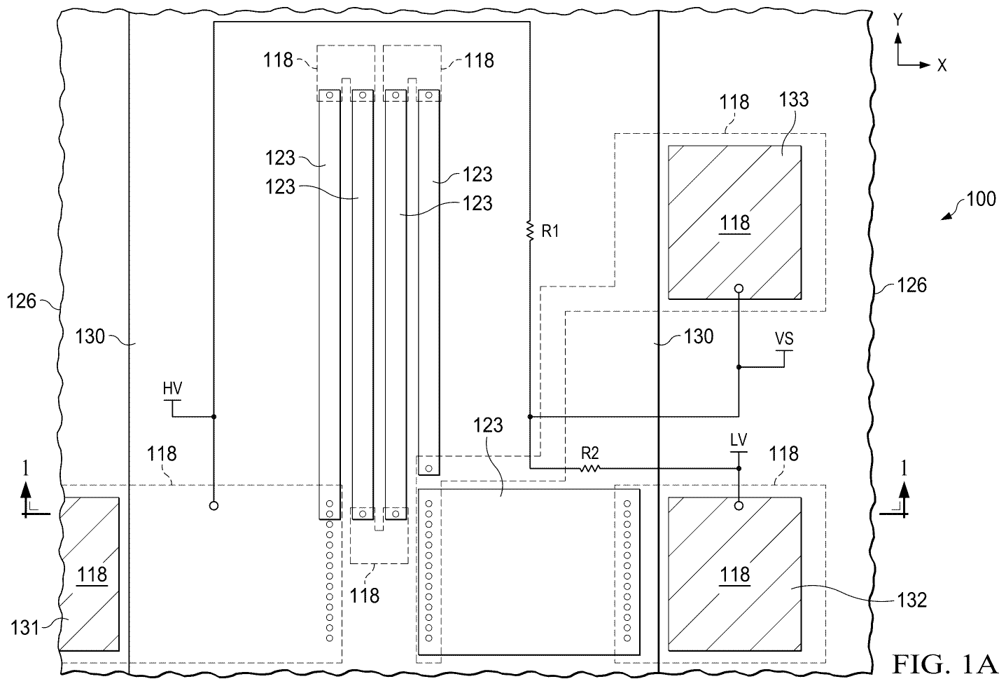

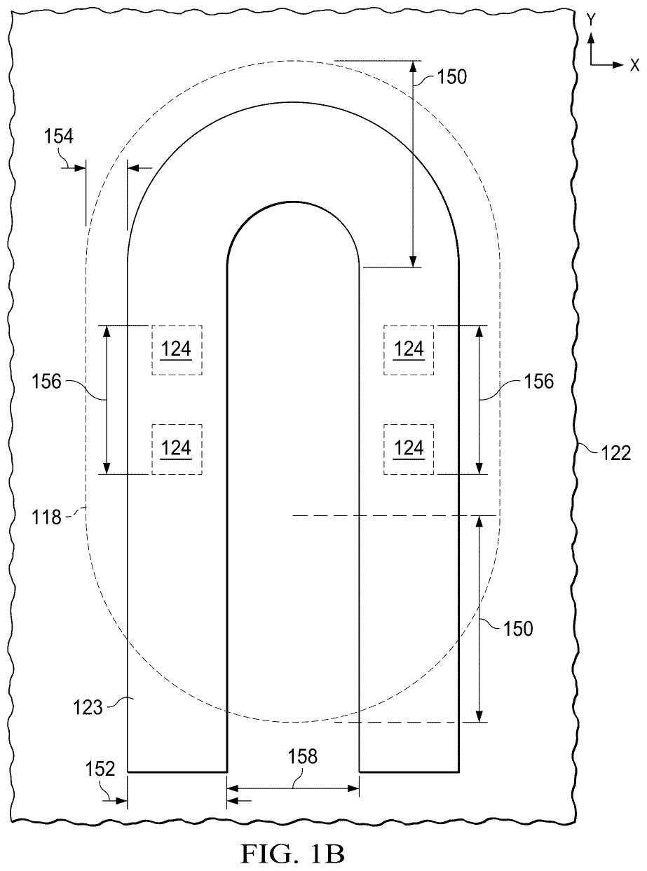

FIGS. 1, 1A and 1B show an integrated circuit 100 (also sometimes referred to herein as an electronic device) with an integrated resistive voltage divider in a multilevel metallization structure over a semiconductor layer 102, sometimes referred to as a substrate 102. Described example electronic devices, such as integrated circuits provide a resistor or resistor network on a die fabricated in a metallization structure located over the silicon substrate semiconductor layer 102. The metallization structure includes silicon dioxide that provide high voltage insulation between the resistors and the underlying semiconductor layer 102. Certain examples enclose or cover the resistors with high electrical breakdown strength dielectric materials and the die is encapsulated within a multichip module (MCM) with mold compound or other package structure 150 that can mitigate or avoid air breakdown over the resistor or resistors to create high voltage isolation with high precision thin film resistors for sensing or other applications. The die in one example is a resistor divider die in a multichip module that is mounted on a lead frame or die attach pad 152 and can be packaged along with one or more additional dies (not shown), such as a sensor circuit die with transistors forming a sensing amplifier. In another example, the resistor or resistor network is included in a die with other circuit components (e.g., one or more transistors, diodes, capacitors, inductors, transformers, etc.) of an integrated circuit, or electronic device, 100.

In one example, the semiconductor layer 102 is or includes a p-type silicon layer, a silicon-germanium layer, a silicon-on-insulator (SOI) structure, or another layer or layers having semiconductor material. The semiconductor layer 102 in some examples may be separated from a starting semiconductor wafer or a semiconductor layer over a wafer, such as an epitaxial layer over a wafer. In various examples the semiconductor layer 102 may be referred to as a semiconductor substrate. In one implementation, the electronic device 100 also includes further circuitry (e.g., low voltage logic circuits, not shown) such as transistors formed on and/or in the semiconductor layer 102.

As shown in FIG. 1, the integrated circuit 100 includes a multilevel metallization structure with a pre-metal dielectric (PMD) layer 103 disposed over (e.g., on and directly contacting) a top side of the semiconductor layer 102, and first and second metallization levels above the pre-metal dielectric PMD layer 103. Other examples can include a different number of metallization levels. In one example, the PMD layer 103 is or includes silicon dioxide (e.g., SiO₂) with a thickness of approximately 3.0 μm. The pre-metal level and the metallization structure levels extend in respective planes of respective orthogonal first and second directions X, Y and are arranged in a stack along a third direction Z that is orthogonal to the first and second directions X and Y. In the illustrated example, the second (e.g., top) level includes resistor terminals having an exposed top side that allows bond wire or other connection to the resistor terminals for electrical coupling to a second die or to device leads or other terminals of the integrated circuit 100.

The first level of the metallization structure has a first interlevel dielectric (ILD) layer 104 above (e.g., on and directly contacting) the PMD layer 103 of approximately 3.0 to 5.0 μm in one example. In one example, the first ILD layer 104 is or includes silicon dioxide with a thickness of approximately 3.0 μm. The PMD level includes conductive contacts 106 and conductive cylindrical peripheral contacts 107 on the semiconductor layer 101, for example, circles having diameters of approximately 0.9 μm or can be a trench that fully surrounds the die as part of a scribe seal. The contacts 106 and 107 in one example are or include tungsten but can be or include one or more other conductive metals and can include low contact resistance metal such as titanium and/or titanium nitride (not shown) in a single or a bilayer structure to interface the top surface of the semiconductor layer 102. The contacts 106 and 107 extend through the PMD layer 103 along the third direction Z in FIG. 1.

The first metallization level in one example has aluminum conductive routing features or traces patterned according to a device design, including a conductive metal grounded fill feature 108 and a peripheral conductive metal seal structure 109 as shown in FIG. 1. The peripheral contacts 107 and the peripheral metal structure 109 near the outer periphery of the illustrated portion of the integrated circuit 100 can help protect against cracks and mechanical stress on the integrated circuit 100 and/or provide a barrier against ingress from external ionic contamination at the die edge, although not a strict requirement of all possible implementations.

In other implementations, different dielectric and/or conductive metal materials can be used (e.g., copper metal features, silicon oxynitride dielectric layers, etc.). The first level also includes a dielectric layer 110 above (e.g., on and directly contacting) the first ILD layer 104. In one example, the dielectric layer 110 is or includes silicon oxynitride of any suitable stoichiometry (e.g., SiOₓN_{y}), and can be referred to as a first silicon oxynitride layer. In one example, the first ILD layer 104 has a planarized top surface that extends above the top surface of the first metal layer conductive features 108 and 109 by approximately 1.4 μm. In one example, the top surface of the dielectric layer 110 is spaced apart from the top side of the semiconductor layer 102 by a distance 140 of approximately 8.3 μm along the third direction Z.

The metallization structure includes a second level with a second ILD layer 112 over (e.g., on and contacting) the dielectric layer 110. In one example, the second ILD layer 112 is or includes silicon dioxide of any suitable stoichiometry and thickness, for example, approximately 6.6 μm. The second level also includes a dielectric layer 114, e.g. silicon oxynitride, over (e.g., on and contacting) the top surface of the second ILD layer 112, for example, approximately 0.3 to 0.8 μm thick, and a dielectric layer 116 over (e.g., on and contacting) a first portion of the dielectric layer 114. In one example, the dielectric layer 116 is or includes an inorganic dielectric material such as silicon nitride (e.g., SiN of any suitable stoichiometry) and can be of any suitable thickness, for example, approximately 0.55 μm as deposited. In one example, the top surface of the dielectric layer 116 is spaced apart from the top surface of the dielectric layer 110 by a spacing distance 141 of approximately 7.4 to 7.9 μm along the third direction Z. In some examples, the high voltage isolation capabilities can be enhanced by use of the silicon oxynitride/silicon nitride or other suitable dielectric bilayer of the dielectric layers 114, 116 under a pad metal layer 118. The bilayer in one example includes silicon nitride for the dielectric layer 116 with the gap G and the silicon oxynitride for the dielectric layer 114. Such a bilayer is sometimes referred to as a silicon nitride/oxynitride (SO) bilayer 114, 116, or simply as “SO bilayer”. A trench in the SO bilayer 114, 116 extends through the silicon nitride layer 116 and partially into the oxynitride layer.

The second metallization level in one example has aluminum conductive routing features or traces such as the pad metal layer 118, referred to herein as a pad metal layer, on the dielectric layer 116 and patterned according to a device design. In other examples, a different metal material can be used. Portions of the pad metal layer 118 are exposed outside a dielectric seal structure 121 including dielectric sublayers 122, 126 to allow electrical connection by bond wires or other suitable conductive connection structures. The features of the pad metal layer 118 of the second level include a first resistor terminal 131 (FIGS. 1 and 1A), a second resistor terminal 132 (FIGS. 1 and 1A, and a third resistor terminal 133 (FIG. 1A)). The illustrated example has a lateral gap G in the dielectric layer 116 between the first and second resistor terminals 131 and 132 with a gap distance 117. In one example, the gap distance 117 is designed based on a voltage rating of the integrated circuit 100 to mitigate or avoid lateral voltage breakdown between high and low voltage domain levels along an interface between the respective dielectric layers 114 and 116 based on an operating voltage between the first and second resistor terminals 131 and 132.

The pad metal layer 118 is covered by a third ILD layer 120 that extends over (e.g., on and directly contacting) the patterned features of the pad metal layer 118 and the top surfaces of the dielectric layer 116 and the dielectric layer 114 in the gap G of the dielectric layer 116. In one example, the third ILD layer 120 is or includes silicon dioxide of any suitable stoichiometry and thickness, for example, approximately 1.0 μm. The integrated circuit 100 also includes a resistor, also referred to as a film resistor, including portions of a thin film resistor (TFR) layer 123 enclosed by first and second sublayers 122 and 126 of the dielectric seal structure 121. The TFR layer 123 is located on the first sublayer 122 of the dielectric seal structure 121, and the second sublayer 126 of the dielectric seal structure is on the TFR layer 123 such that the seal structure 121 encapsulates the TFR layer 123. In one example, the first and second sublayers 122 and 126 are or include silicon oxynitride of any suitable stoichiometry and thicknesses, such as approximately 0.2 μm and 0.1 μm, respectively).

As further shown in FIG. 1, the integrated circuit 100 in one example has a further dielectric layer 128 over (e.g., on and directly contacting) a top surface of the second sublayer 126 of the dielectric seal structure 121. In one example, the dielectric layer 128 is or includes silicon dioxide of any suitable stoichiometry and thickness, for example, approximately 1.0 μm. Another dielectric layer 129 is located over (e.g., on and directly contacting) a top surface of the dielectric layer 128. In one example, the dielectric layer 129 is or includes silicon oxynitride of any suitable stoichiometry and thickness, for example, approximately 2.8 μm. The dielectric layers 128 and 129 in one example form a bilayer protective overcoat (PO) 134 as shown in FIG. 1, which is located over the TFR layer 123. The protective overcoat 134 in one example has a thickness of at least 10 μm along the third direction Z. The protective overcoat 128, 129 in one example includes an inorganic dielectric layer 129 (e.g., SiON) and an inorganic dielectric layer 128 (e.g., SiO₂). In the illustrated example, openings in the dielectric layer 129 and the underlying layers 128, 126, 122, and 120 expose the first and second resistor terminals 131, 132, and 133. The integrated circuit 100 in one example also includes a polyimide (PI) layer 130 over (e.g., on and directly contacting) the dielectric layer 129. In one example, the protective overcoat 128, 129 is located over the TFR layer 123 and includes an dielectric layer (e.g., SiON layer 129), and the polyimide dielectric layer (130) is located over the protective overcoat (128, 129). Openings in the dielectric layer (129) and the protective overcoat (128, 129) expose the first and second resistor terminals 131 and 132.

FIG. 1A shows a top view of the integrated circuit 100 including a schematic circuit drawing. The TFR layer 123 is located over portions of the pad metal layer 118 and are connected to the pad metal layer 118 by vertical metal interconnects or vias 124 as shown in FIG. 1. In one example patterned features of the TFR layer 123, which may include silicon and chromium (e.g., SiCr) of any suitable thickness and stoichiometry, forms a first resistor R1 and a second resistor R2 as shown in FIG. 1A. In one example, the TFR layer 123 comprises silicon (Si), chromium (Cr) and carbon (C) (e.g., SiCCr) of any suitable thickness and stoichiometry. As shown in FIG. 1, a first location of the TFR layer 123 is connected to the first resistor terminal 131 by a first vertical interconnect 124, and a second location of the TFR layer 123 is connected to the second resistor terminal 132 by a second vertical interconnect 124. In one example, the vertical interconnects 124 include a low contact resistance metal layer (single or bilayer, such as titanium and titanium nitride of any suitable thickness and stoichiometry) along bottoms and sidewalls of corresponding cylindrical via holes or openings through the first sublayer 122 of the dielectric seal structure 121 and the third ILD layer 120. The vertical interconnects 124 are filled with conductive metal, such as tungsten in one example, to provide a low impedance electrical connection of the first location of the TFR layer 123 to the first resistor terminal 131 and of the second location of the TFR layer 123 to the second resistor terminal 132.

As shown in FIG. 1A, moreover, the first resistor R1 has a serpentine shape extending in the TFR layer 123 along the second direction Y and turnaround end portions in the pad metal layer 118. As further shown in FIG. 1A, moreover, the third resistor terminal 133 is connected to a node that joins the first and second resistors R1 and R2 to form a resistive divider sensing node labeled “VS” in FIG. 1A. The first resistor R1 is connected between the first terminal (e.g., which can be connected to a high voltage node of the integrated circuit 100, labeled “HV” in FIG. 1A) and the third resistor terminal 133 at the sensing node VS. The example second resistor R2 of the resistive divider arrangement is connected between the second resistor terminal 132 at a low voltage node (e.g., labeled “LV” in FIG. 1A) of the integrated circuit 100 and the third resistor terminal 133.

Referring also to FIG. 1B, in one implementation, the TFR resistor R1 includes a continuous serpentine structure between the first and second locations of the film resistor 123. FIG. 1B shows an example turnaround portion in the TFR layer 123 between two illustrated portions of adjacent linear parallel resistor segments. A “turnaround” is defined as a conductive structure that connects adjacent, or nearest neighbor, ends of linear portions of the resistor. In some examples a turnaround in the TFR layer has a constant radius of curvature between the end of one linear portion and the end of another linear portion. In some examples a turnaround in the pad metal layer 118 may be circular, ovoid, elliptical or obround. In some examples, the serpentine structure extends between the high and low voltage nodes, wherein “high voltage” may mean a voltage with respect to the low voltage node exceeding 1000 volts (1 kV). The example portion of the serpentine structure in FIG. 1B includes top metal turnarounds in the pad metal layer 118 and redundant turnarounds in the TFR layer 123. The redundancy provided by the serpentine structure the resistor R1 provides a level of electrical redundancy that may benefit yield and reliability. In certain examples, the turnarounds of the pad metal layer 118 are connected to respective turnarounds in the TFR layer 123 by via structures 124. The via structures 124 may be located near ends of the linear resistor segments and/or in the turnaround portion, and may be square or rectangular. In one example, the via structures 124 may have a longitudinal length 156 along a long axis of approximately 1.2 μm, and a lateral width along a perpendicular short axis of 0.4 μm. In one implementation, a radius of curvature 150 of the turnaround portion of the pad metal layer 118 is approximately 1.6 μm, the linear segments of the TFR layer 123 have lateral widths 152 along the first direction X of approximately 0.8 μm, the pad metal layer turnaround features extend laterally beyond the linear segments of the TFR layer 123 in the X direction by a spacing distance 154 of approximately 0.2 μm, and the segments of the TFR layer 123 are spaced apart from one another by a spacing distance 158 of approximately 1.2 μm.

As further shown in FIG. 1, the TFR layer 123 is spaced apart from the semiconductor layer 102 by a spacing distance 145 along the third direction Z. In the illustrated example, the high voltage node (HV) at the first resistor terminal 131 is spaced apart from the semiconductor layer 102 along the third direction Z by a spacing distance 142 determined according to a rated operating voltage of the integrated circuit 100 (e.g., greater than approximately 10 μm). In one implementation, the spacing distance 142 is approximately 15 μm or more (e.g., approximately 16 μm) and the pad metal layer 118 is at least 15 μm above the top surface of the semiconductor layer 102.

The top surfaces of the conductive metal grounded fill feature 108 and the peripheral conductive metal seal structure 109 of the first metallization level (connected to the substrate 102) are below and spaced apart from the second resistor terminal 132 along the third direction Z by a spacing distance 143 (FIG. 1, e.g., approximately 10 μm) to accommodate a rated operating voltage of the low voltage node (LV) at the second resistor terminal 132 without voltage breakdown. The first resistor R1 in this example has a high voltage and the spacing distance 145 between the resistor R1 and the semiconductor layer (substrate) 102. In one example, the bottom surface of the polyimide layer 130 is spaced apart from the top surface of the pad metal layer 118 along the third direction Z by a spacing distance 144 of approximately 5.1 μm. In one example, the polyimide layer 130 has a thickness 146 along the third direction Z of approximately 8-10 μm. In one example, the bottom surface of the polyimide layer 130 is spaced apart from the top surface of the TFR layer 123 along the third direction Z by a spacing distance 147 of approximately 3.9 μm.

As further shown in FIG. 1, the gap G in the dielectric layer 116 extends between the first and second resistor terminals 131 and 132. In this example, moreover, the resistor R1 having the high voltage drop is positioned at least partially over (e.g., above) the gap G in the dielectric layer 116. The integrated circuit 100 in the illustrated example includes a first bond wire 161 connected to the first resistor terminal 131, a second bond wire 162 connected to the second resistor terminal 132, and a third bond wire 163 connected to the third resistor terminal 133. The integrated circuit 100 in one example includes a molded package structure 150, such as a plastic epoxy mold compound (EMC) or ceramic package that encloses the multilevel metallization structure and the bond wires 161-163 and the die is mounted to a support structure such as die attach pad 152, such as a die attach pad of a starting lead frame.

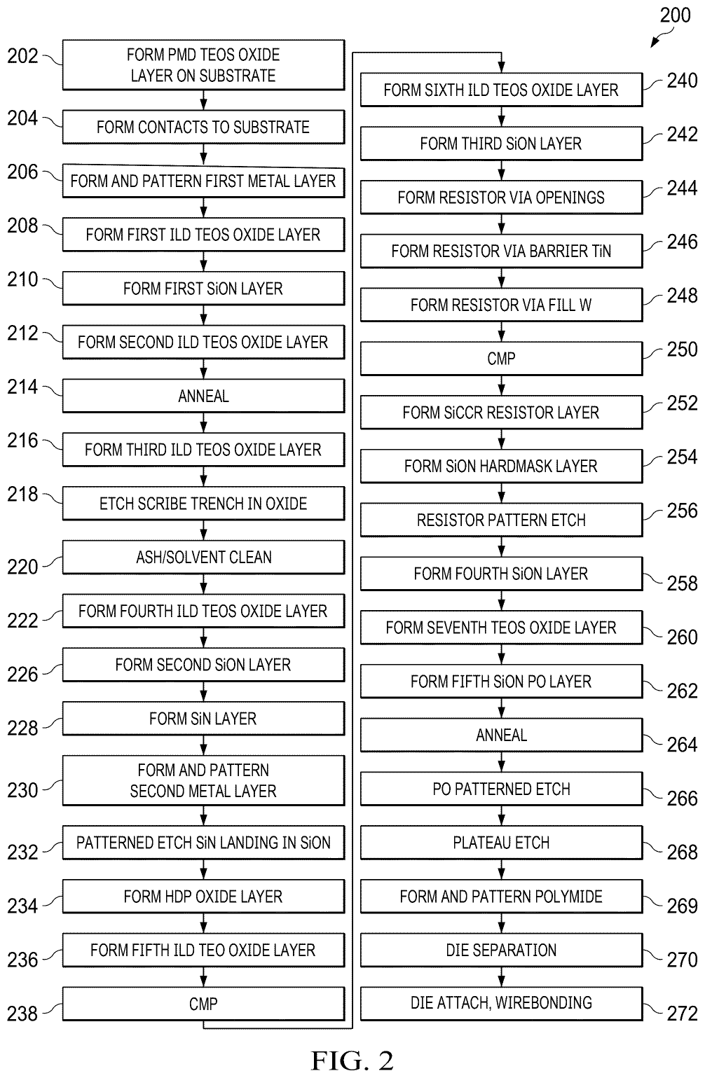

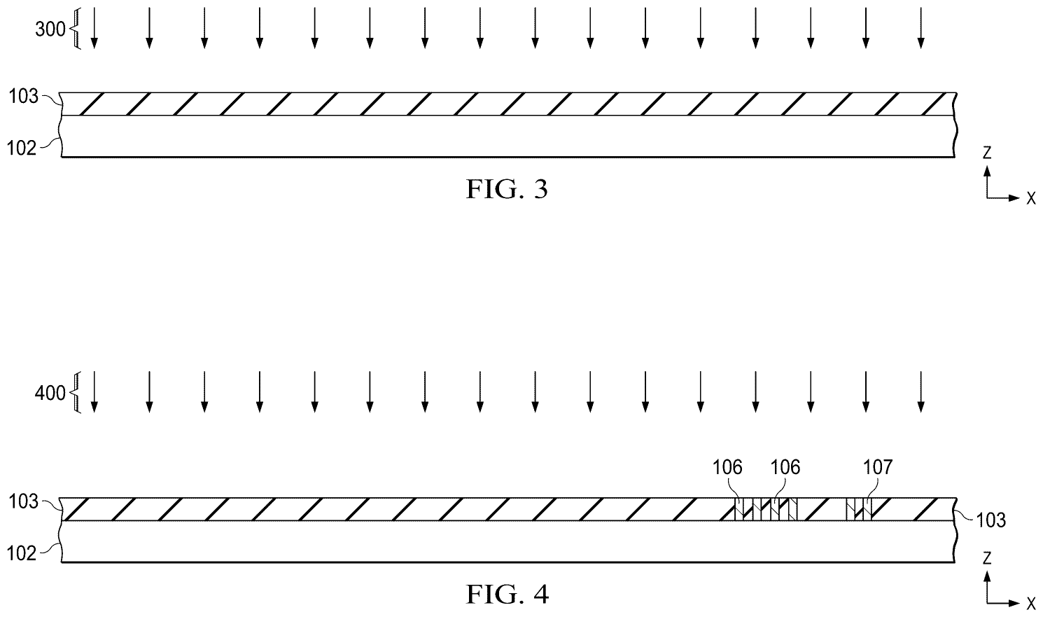

Referring also to FIGS. 2-37, FIG. 2 shows a method 200 of fabricating an electronic device, such as an integrated circuit, and FIGS. 3-37 show the integrated circuit 100 FIGS. 1 and 1A undergoing fabrication processing according to the method 200. The described steps may concurrently be used to fabricate and interconnect other electronic circuits and/or components (e.g., transistor circuits, other isolation circuits, etc.) in a single semiconductor die. The metallization structure in one example includes metal lines, cylindrical contacts and vias and/or trench contacts and vias that electrically couple terminals of the thin film resistor R1 to one or more internal components (e.g., the second resistor R2 in the resistive divider circuit example described above).

The method 200 can include front end processing (not shown), for example, to fabricate one or more circuit components (e.g., transistors, etc.) on and/or in a starting wafer (e.g., on and/or in the semiconductor layer 102 above). In one example, the front-end processing includes processing of a starting semiconductor wafer, such as a p-type silicon wafer, a SOI structure with a silicon layer, a silicon-germanium layer, or another layer having semiconductor material and can include forming isolation structures, such as shallow trench isolation (STI) structures (not shown) on and/or in a top side of the semiconductor layer 102.

The method 200 includes fabricating a metallization structure over the semiconductor layer 102 including forming a pre-metal dielectric layer at 202. FIG. 3 shows one example of the processing at 202, in which a deposition process 300 is performed that deposits the PMD layer 103 (e.g., SiO₂) on the semiconductor layer 102. In one example, the process 300 deposits silicon dioxide to form the PMD layer 103 to a thickness of approximately 2.9 μm.

The method 200 continues at 204 in FIG. 2 with forming contacts (e.g., contacts 106 and 107) through the PMD layer 103. FIG. 4 shows one example, in which a contact formation process 400 is performed that forms contacts 106 and peripheral contacts 107 through the PMD layer 103 and on the semiconductor layer 102. In one example, the process 400 includes patterned etching (not shown) to form cylindrical holes and/or trenches for the respective contacts, and one or more deposition steps that deposit suitable metal (e.g., that is or includes tungsten) in the openings, followed by a planarization step (e.g., chemical mechanical polishing or CMP) to provide a planar top side of the PMD layer 103 and the formed respective contacts 106 and 107. In one example, the contacts 107 are formed at 204 in regions near the outer periphery of the illustrated portion to provide protection against cracks and mechanical stress on the integrated circuit 100 as well as provide a barrier against ingress from external ionic contamination at the die edge, although not a strict requirement of all possible implementations.

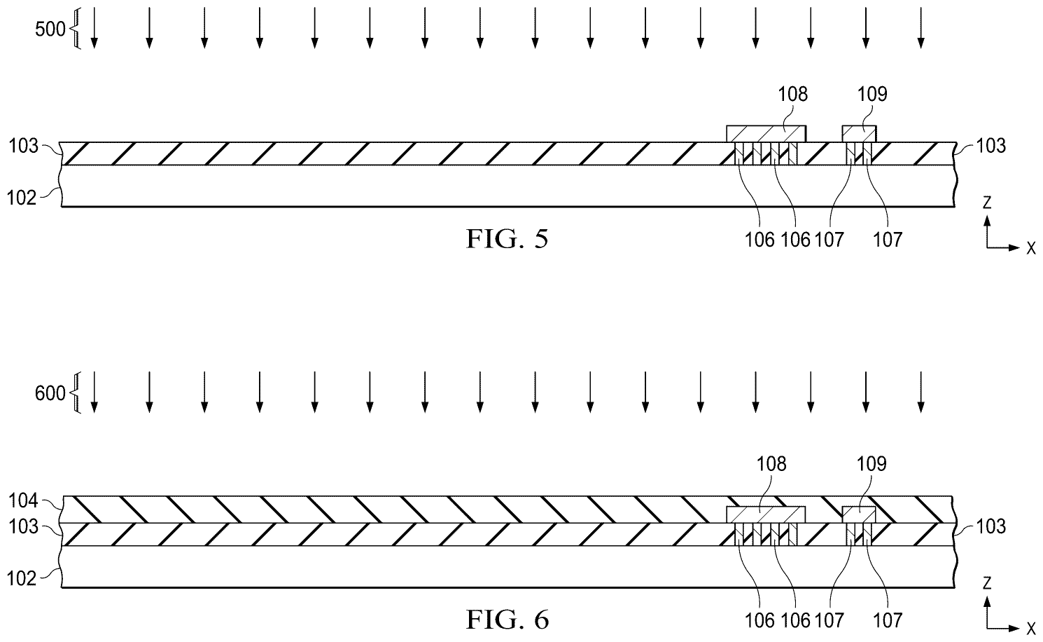

The method 200 continues at 206 in FIG. 2 with forming the first metallization structure level over the PMD layer 103. The first metallization level includes the metal features 108 and 109 on the respective contacts 106 and 107. FIG. 5 shows one example, in which a process 500 is performed that deposits a conductive metal layer on the PMD layer 103 (e.g., aluminum to a thickness of approximately 3.0 μm), and etches exposed portions of the deposited metal using a patterned etch mask (not shown) to form the conductive metal grounded fill feature 108 and peripheral conductive metal seal structure 109.

At 208 in FIG. 2, the first ILD layer 104 is deposited on the PMD layer 103. FIG. 6 shows one example, in which a process 600 is performed that deposits and planarizes the first ILD layer 104 on the PMD layer 103. In one example, the process 600 is a plasma enhanced chemical vapor deposition (PECVD) deposition process that forms a silicon dioxide layer as a tetraethyl orthosilicate (e.g., tetraethoxysilane or TEOS oxide) ILD layer 104 to a thickness over the first metal layer features of approximately 1.4 μm and a thickness over the PMD layer 103 of approximately 3.0 to 4.4 μm following planarization by chemical mechanical polishing (CMP).

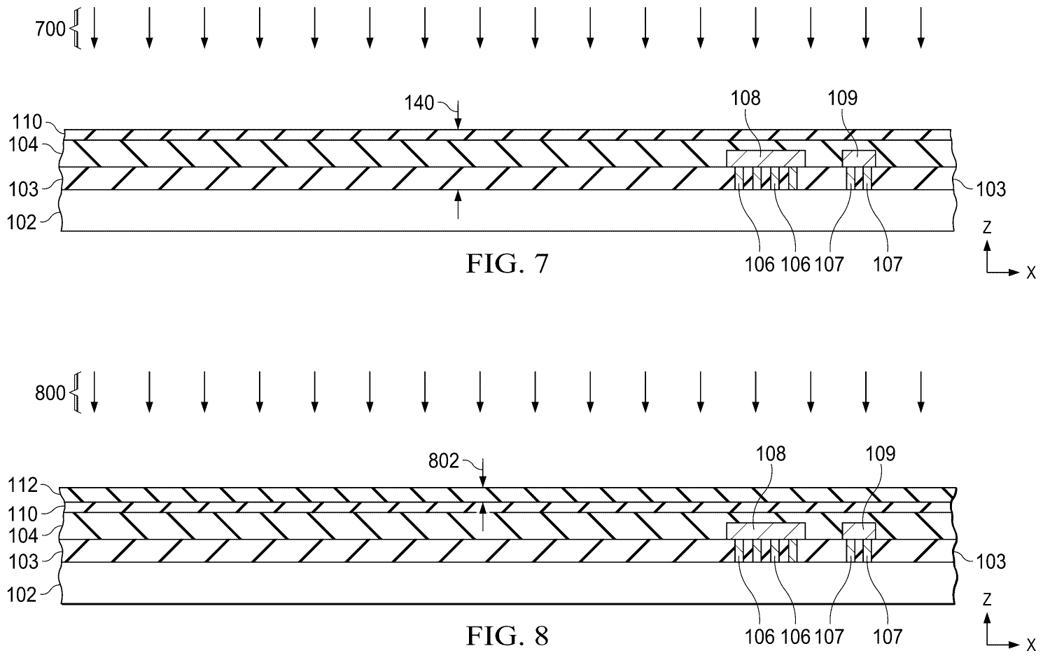

At 210 in FIG. 2, a first dielectric layer is formed over the first ILD layer 104. FIG. 7 shows one example, in which a deposition process 700 is performed that forms the dielectric layer 110 above (e.g., on and directly contacting) the first ILD layer 104. In one example, the dielectric layer 110 is or includes silicon oxynitride of any suitable stoichiometry (e.g., SiOₓN_{y}, such as SiON₃), and can be referred to as a first silicon oxynitride layer. In one example, the top surface of the dielectric layer 110 is spaced apart from the top side of the semiconductor layer 102 by the distance 140 of approximately 8.3 μm along the third direction Z.

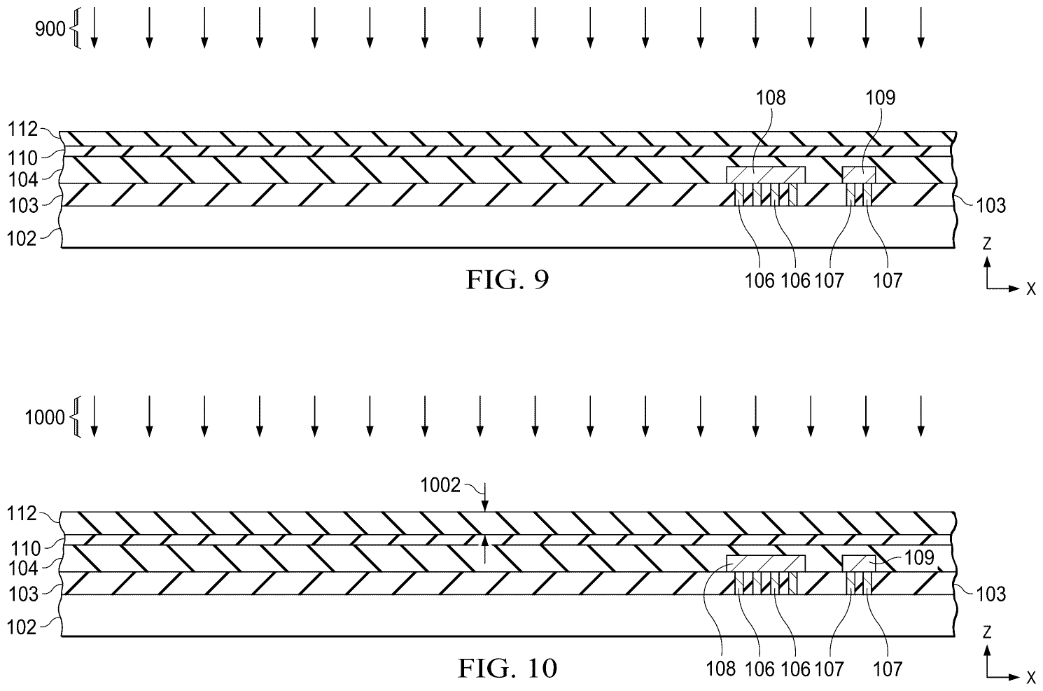

At 212 in FIG. 2, a second ILD layer is formed, for example, a second oxide dielectric layer over the dielectric layer 110. FIG. 8 shows one example, in which a PECVD deposition process 800 is performed that forms the second ILD layer 112 over (e.g., on and contacting) the top surface of the dielectric layer 110 to a thickness 802 of approximately 3.6 μm. At 214 in FIG. 2, a thermal process is performed, for example, to increase tensile strength of the first metal structures 108 and 109 for wafer bow compensation benefits. FIG. 9 shows one example, in which a thermal annealing process 900 is performed that anneals the structure. At 216 in FIG. 2, a further (e.g., third) TEOS oxide layer is formed. FIG. 10 shows one example, in which a PECVD process 1000 is performed that forms further TEOS silicon dioxide of the second ILD layer 112 to provide an increased thickness 1002.

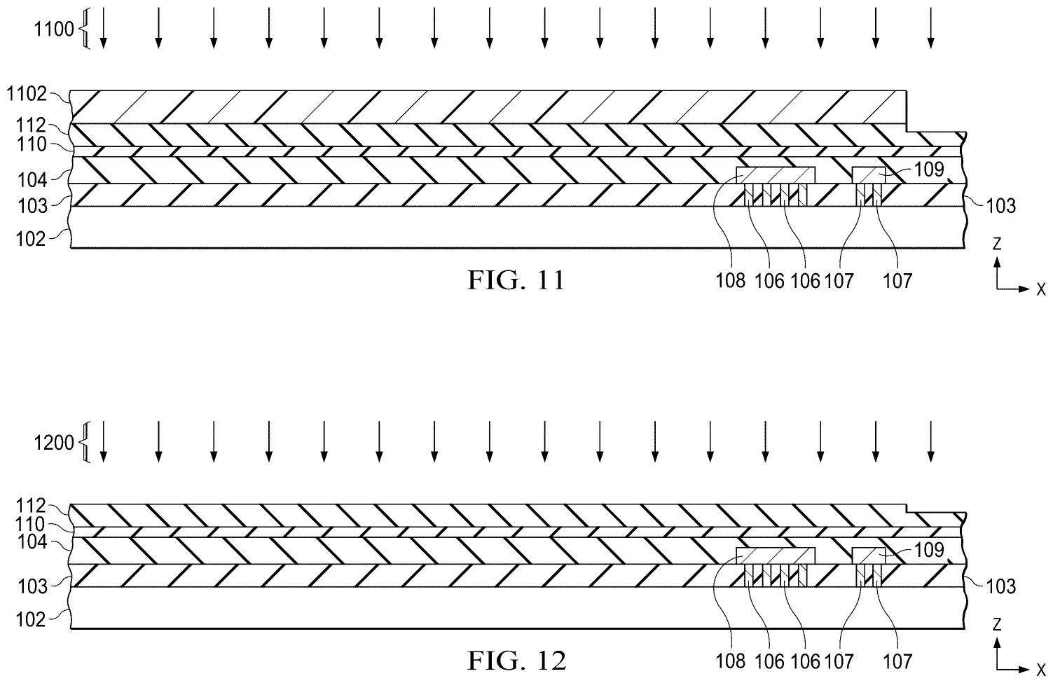

At 218 in FIG. 2, an etch process is performed to form a scribe trench in the second ILD layer 112. FIG. 11 shows one example, in which an etch process 1100 is performed using an etch mask 1102 to form a trench in an exposed peripheral portion of the second ILD layer 112, for example, to a depth of approximately 0.5 μm to create alignment marks for subsequent second-level metal patterning. In one implementation, the method 200 includes a post-etch cleaning process at 220 in FIG. 2. FIG. 12 shows one example, in which a post-etch ash/solvent clean/ash process 1200 is performed that cleans the top surface of the second ILD layer 112 including the etched trench.

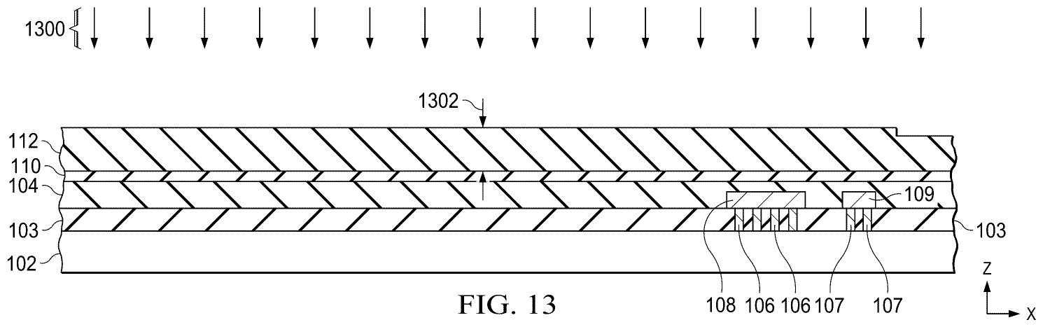

At 222 in FIG. 2, the thickness of the second ILD layer 112 is again increased in one example by depositing further silicon dioxide. FIG. 13 shows one example, in which another (e.g., fourth) TEOS oxide deposition process 1300 is performed that forms further TEOS silicon dioxide of the second ILD layer 112 to provide a final thickness 1302 of approximately 6.6 μm, with a contoured edge formed by the recently etched scribe trench.

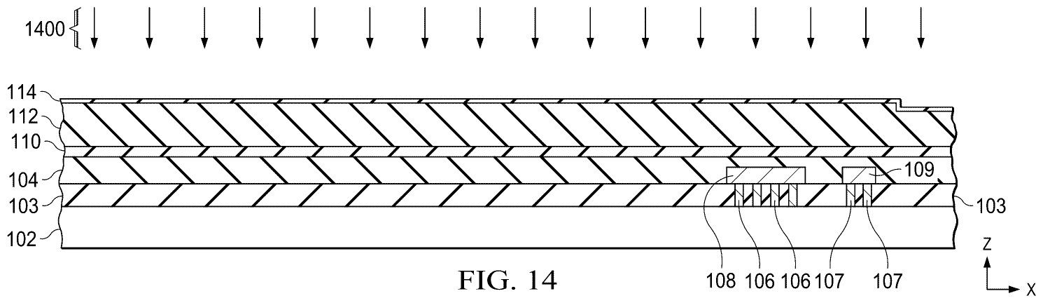

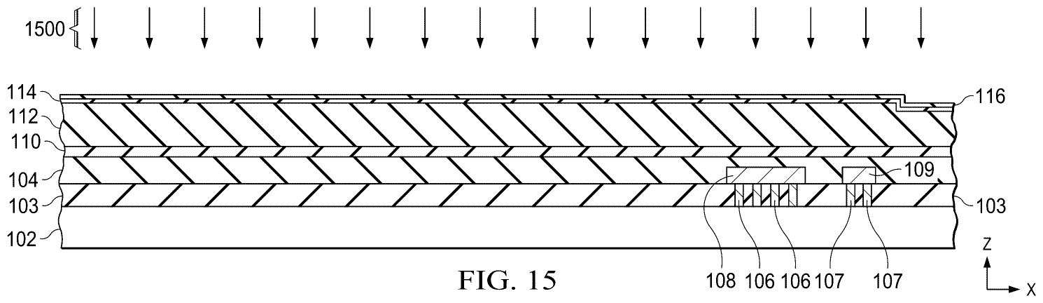

At 226 and 228 in FIG. 2, an SO bilayer is formed on the second ILD layer 112. At 226, another dielectric layer is formed above the second ILD layer 112. FIG. 14 shows one example, in which a deposition process 1400 is performed that forms the dielectric layer 114 over (e.g., on and contacting) the top surface of the second ILD layer 112, for example, to a thickness of approximately 0.3 to 0.5 μm. At 228 in FIG. 2, a silicon nitride layer is formed over the dielectric layer 114. FIG. 15 shows one example, in which a deposition process 1500 is performed that forms the dielectric layer 116 over (e.g., on and contacting) the top surface of the dielectric layer 114.

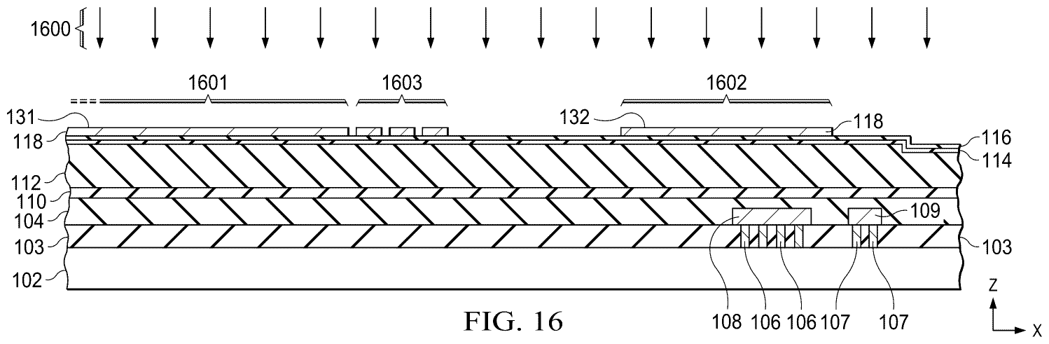

At 230 in FIG. 2, the second level conductive metal features are formed. FIG. 16 shows one example, in which a process 1600 is performed that deposits and patterns the features of the pad metal layer 118, including the resistor terminals 131-133 described above, where the third resistor terminal 133 is not shown in the section view of FIG. 16. The process 1600 in one example includes deposition of an aluminum layer and selective etching of the deposited aluminum to form a first patterned metal feature 1601 that includes the first resistor terminal 131, a second patterned metal feature 1602 that includes the second resistor terminal 132, and further patterned metal features 1603 that provide the turnaround end portions of the serpentine first resistor R1 in the pad metal layer 118 as described above in connection with FIG. 1A in the section view of FIG. 16.

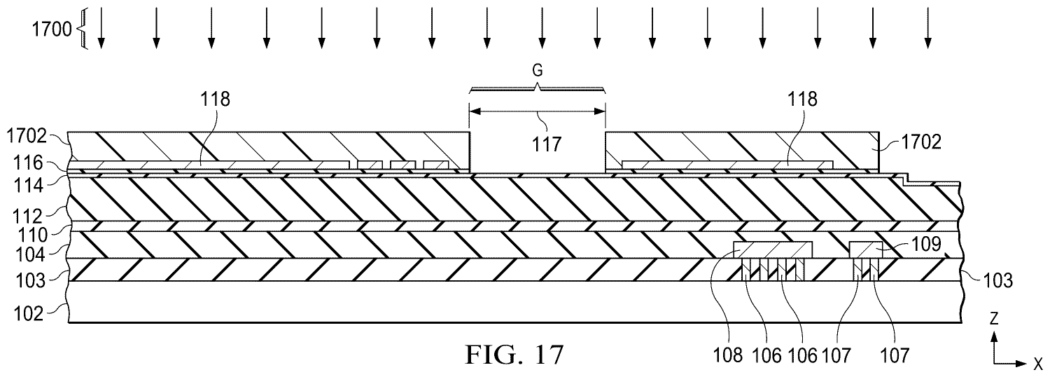

The method 200 continues at 232 in FIG. 2 with selective etching of the SO bilayer 114, 116. FIG. 17 shows one example, in which an etch process 1700 is performed using an etch mask 1702 to etch the exposed portion of the dielectric layer 116 to form the SO relief (SOR) gap G with the gap distance 117, where the SO bilayer 114, 116 has a discontinuity in the interface between the layers 114 and 116 along the gap distance 117 of the gap G. In one example, the first opening in the etch mask 1702 provides a gap distance 117 of approximately 5.0 μm or more. In one example, the etch mask 1702 has another opening (e.g., on the right side of FIG. 17) to start etching near the prospective die boundary to reduce the burden on the subsequent plateau etch (e.g., at 268 in FIG. 2) to etch down to below the surface of the first metal layer feature 109. In one implementation, a cleaning step is included in the process 1700, such as an ash/solvent clean, and the process 1700 in one example removes the exposed SiN layer 116 and lands in the SiON dielectric layer 114 to leave the remaining thickness of the dielectric layer 114 of approximately 0.25 μm or more within the SOR gap G.

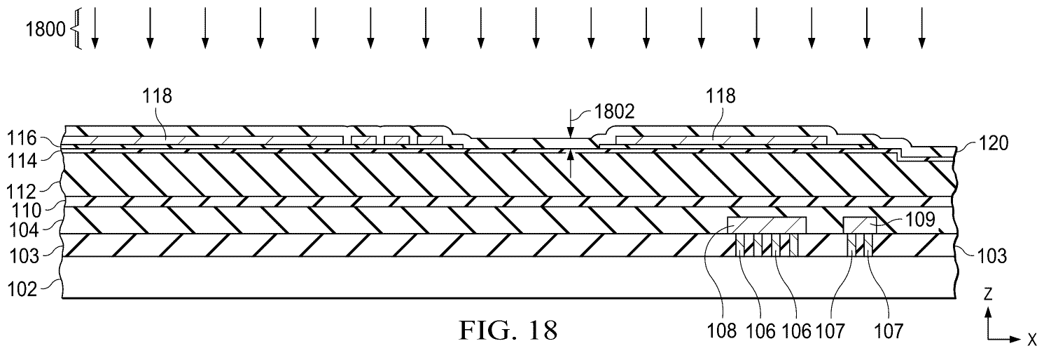

At 234-240 in FIG. 2, the third ILD layer 120 is formed over (e.g., on and directly contacting) the patterned features of the pad metal layer 118 and the top surfaces of the silicon dielectric layer 116 and the dielectric layer 114 in the gap G of the dielectric layer 116. At 234, a high density plasma (HDP) oxide deposition is performed. FIG. 18 shows one example, in which an HDP deposition process 1800 is performed that deposits silicon dioxide to form a first portion of the third ILD layer 120 on the patterned features of the pad metal layer 118 and the top surfaces of the dielectric layer 116 and the dielectric layer 114 in the gap G of the dielectric layer 116. The HDP process 1800 in one example forms the initial silicon dioxide to a thickness 1802 of approximately 0.6 μm.

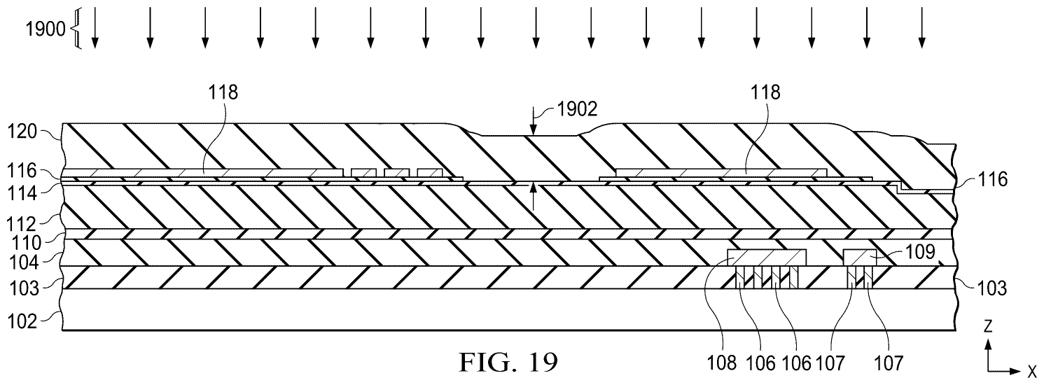

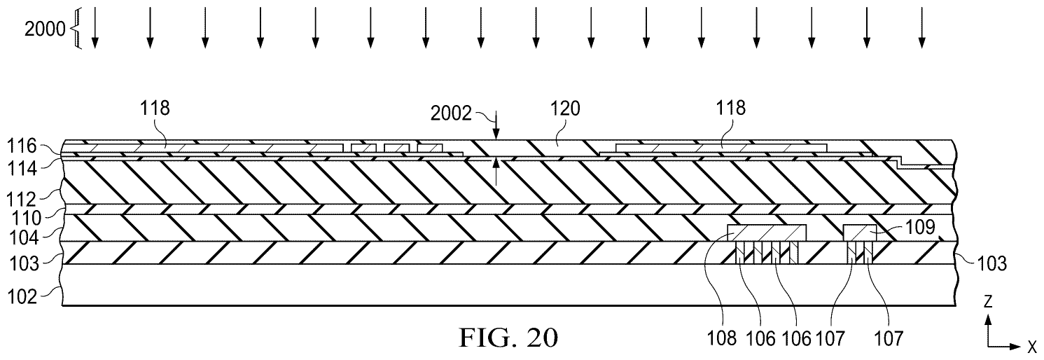

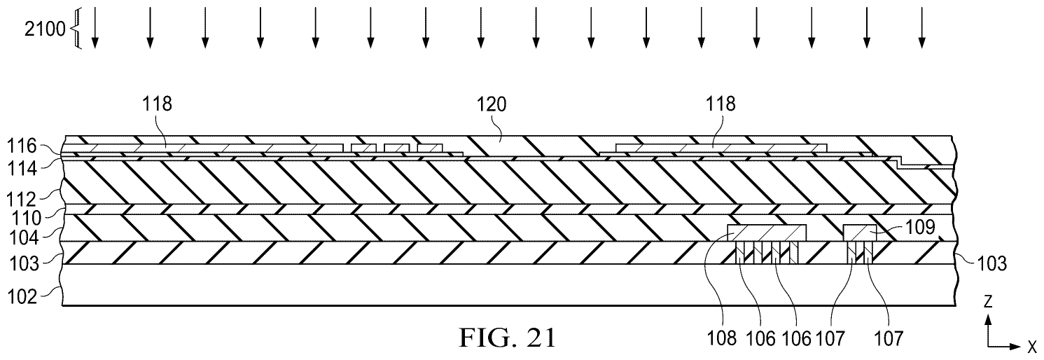

At 236 and FIG. 2, another oxide deposition is performed to increase the thickness of the third ILD layer 120. FIG. 19 shows one example, in which a PECVD process 1900 is performed that deposits TEOS silicon dioxide as a dielectric layer to a thickness 1902 including the HDP oxide of approximately 3.3 μm. At 238 in FIG. 2, the method 200 in one example also includes a planarization step (e.g., CMP). FIG. 20 shows one example, in which a CMP process 2000 is performed that planarize is the top surface of the third ILD layer 120 to provide a third ILD layer thickness 2002 of approximately 2.3 μm. At 240 in FIG. 2, the method 200 continues with forming a further (e.g., sixth) TEOS silicon dioxide of the third ILD layer 120. FIG. 21 shows one example, in which another PECVD deposition process 2100 is performed that deposits a further TEOS oxide, for example, to add an additional 0.5 μm to the thickness of the third ILD layer 120.

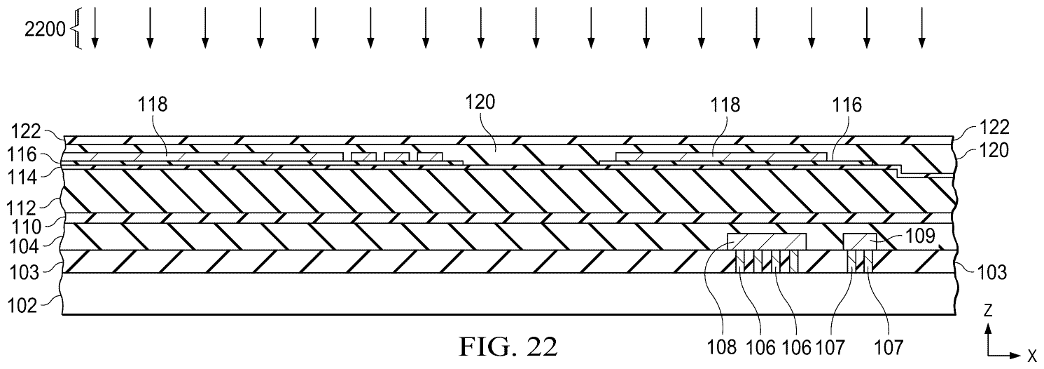

At 242 in FIG. 2, a bottom sub-layer (e.g. the dielectric layer 122 in FIG. 1 above) of a hermetic seal structure is formed over (e.g., on and directly contacting) the top surface of the third ILD layer 120. FIG. 22 shows one example, in which a deposition process 2200 is performed that deposits dielectric layer 122 (e.g., a silicon oxynitride layer) of any suitable stoichiometry and thickness over the third ILD layer 120 (e.g., approximately 2.8 μm).

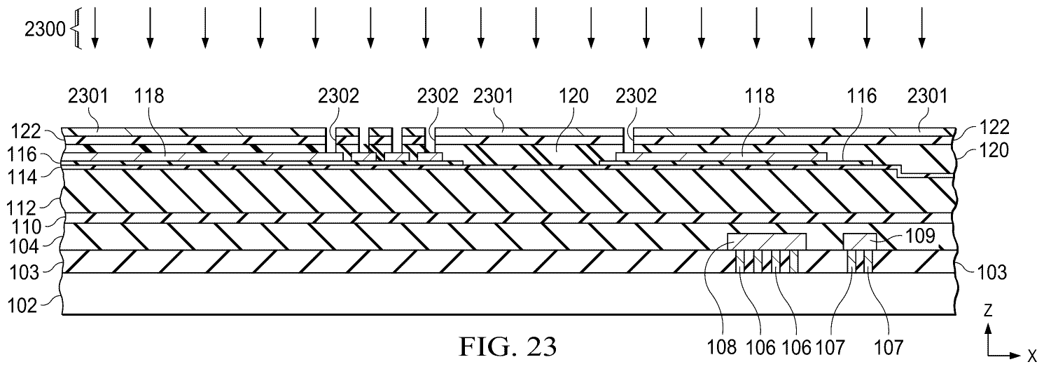

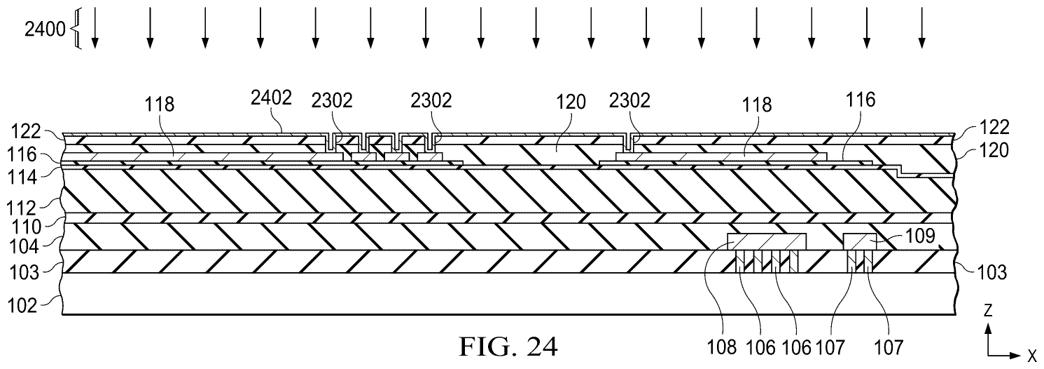

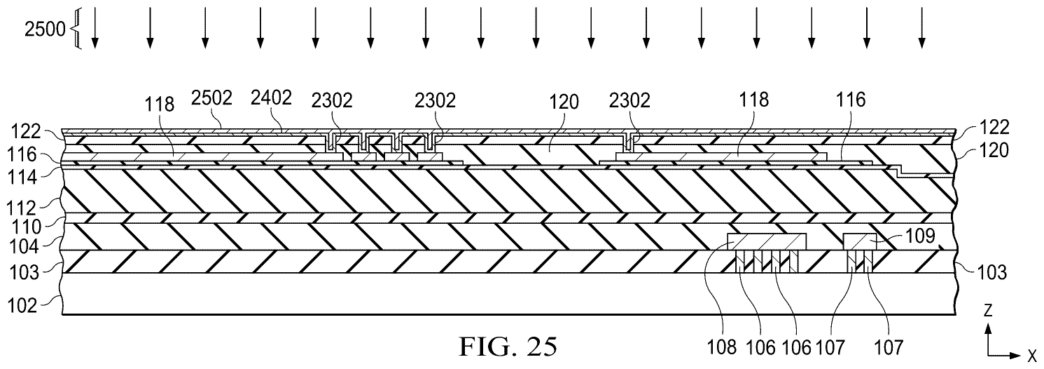

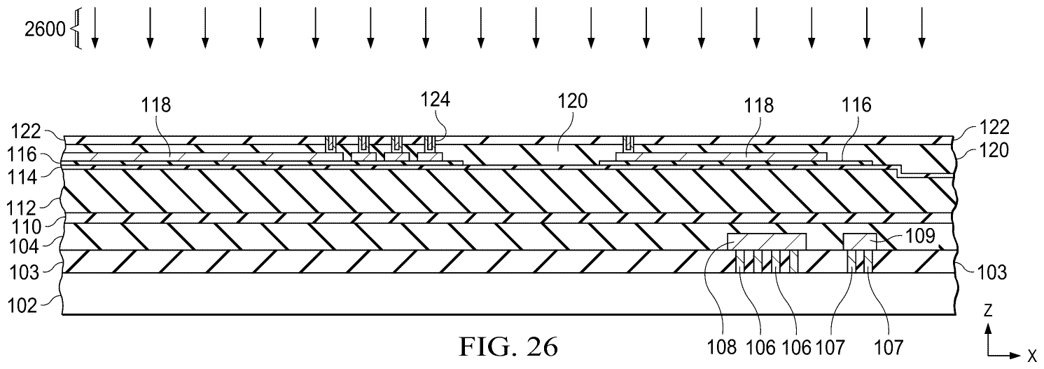

At 244-250 in FIG. 2, conductive metal vias or contacts are formed through the third layer 122 and the third ILD layer 120 to form connections to patterned features of the pad metal layer 118. The contact formation includes forming resistor contact via openings at 244 in FIG. 2. FIG. 23 shows one example, in which an etch process 2300 is performed using an etch mask 2301 to form resistor contact via openings 2302 through the dielectric layer 122 and the third ILD layer 120, for example, cylindrical or square openings of approximately 0.4 μm×0.4 μm of via pairs spaced by approximately 0.4 μm. In one example, the processing 2300 includes etching and post etch cleaning steps. At 246 in FIG. 2, a resistor via barrier metal is formed in the resistor contact via openings 2302. FIG. 24 shows one example, in which a deposition process 2400 is performed that deposits titanium nitride 2402 (TiN) in the openings 2302 and on the top side of the dielectric layer 122. At 248 in FIG. 2, the method 200 continues with filling the contact via openings with conductive metal. FIG. 25 shows one example, in which a deposition process 2500 is performed that deposits tungsten 2502 or other suitable conductive metal on the titanium nitride 2402 in the openings 2302. At 250 in FIG. 2, the structure is CMP′d to remove metals from the field between vias. FIG. 26 shows one example, in which a CMP process 2600 is performed that removes titanium nitride 2402 and tungsten 2502 from the top side of the dielectric layer 122, leaving the remaining resistor contact vias to provide conductive vertical interconnects 124 for electrical connection from the resistor terminals of the pad metal layer 118 to subsequently formed thin film resistors. In one example, the process 2600 further includes a 50 Å oxide etch sputter clean to remove any remnant tungsten oxide (WₓO_{y}) from the surface of the tungsten plugs.

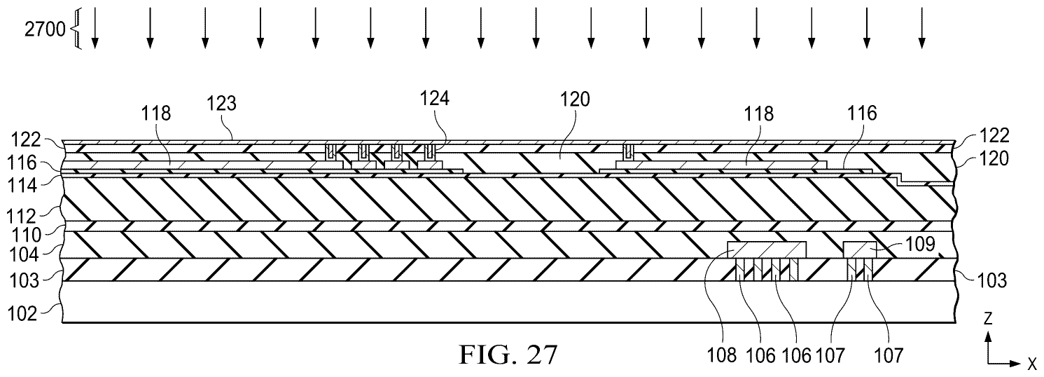

At 252-256 in FIG. 2, the thin film resistors are formed. At 252, a resistor film layer is formed. FIG. 27 shows one example, in which the TFR layer 123 is deposited to any suitable thickness using a deposition process 2700. In one example, the TFR layer 123 is or includes silicon and chromium. In one implementation, the TFR layer 123 is or includes SiCr of any suitable stoichiometry and thickness. In another implementation, the TFR layer 123 is or includes silicon, chromium, and carbon, such as SiCCr of any suitable stoichiometry and thickness (e.g., approximately 32 Å).

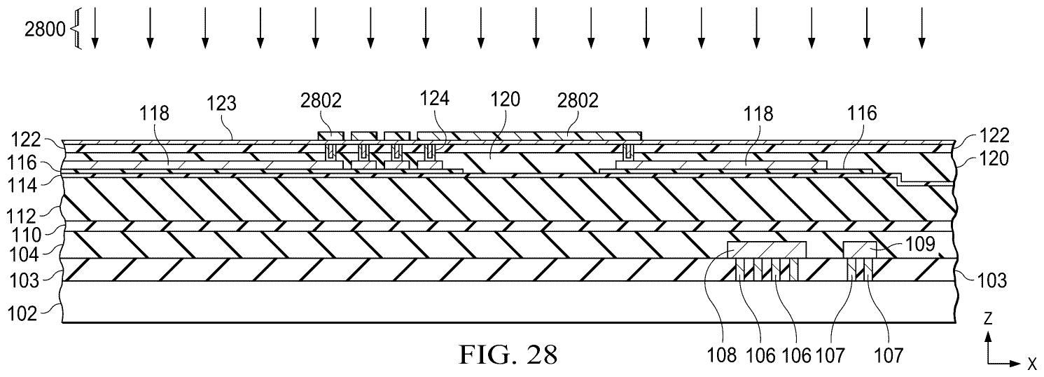

At 254 in FIG. 2, a protective layer is formed for patterning the TFR layer 123. FIG. 28 shows one example, in which a protective layer deposition and patterning process 2800 is used to pattern a protective layer 2802 over the regions where the thin film resistors will be formed. In the illustrated example, the protective layer 2802 is or includes silicon oxynitride of any suitable thickness and stoichiometry (e.g., approximately 300 Å) over the wafer. In one implementation, a bottom antireflective coating (BARC) layer (not shown) is then applied over the entire wafer, and a photoresist layer (not shown) is formed over the BARC layer and patterned. In this example, an etch is performed to remove the BARC layer and the protective mask except under the photoresist and BARC under the resist, and then to selectively remove the exposed portions of the TFR layer 123 in the exposed regions of the TFR layer 123, after which the photoresist and remaining BARC are removed. The protective layer 2802 can help to mitigate or prevent the photoresist strip process from chemically modifying the TFR resistor. In one example, the TFR layer 123 is transparent to optical wavelengths used to pattern the photoresist and may be subject to pattern variability from underlying metal reflections without the use of the BARC layer. Thus, the BARC layer or other suitable photolithographic light transmission blocking layer can be used to facilitate precise linewidth control.

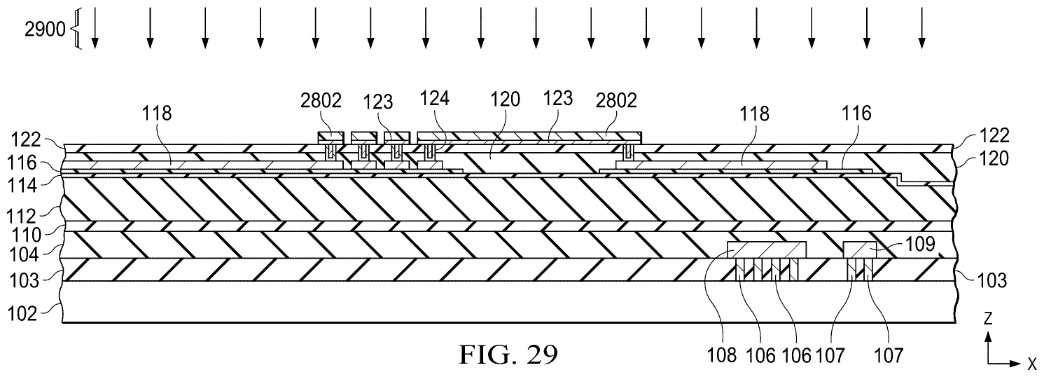

At 256 in FIG. 2, the TFR layer 123 is etched to form the desired patterned thin film resistor features (e.g., resistors R1 and R2 described above in connection with FIGS. 1 and 1A). FIG. 29 shows one example, in which an etch process 2900 is performed using the patterned protective layer 2802 (including photoresist and BARC layer, if used) to selectively etch the TFR layer 123. An O₂ ash process followed by a dilute HF clean can be used to remove the resist 2802 and underlying BARC. In another implementation, the processing 2900 can include a post-ash solvent cleaning step.

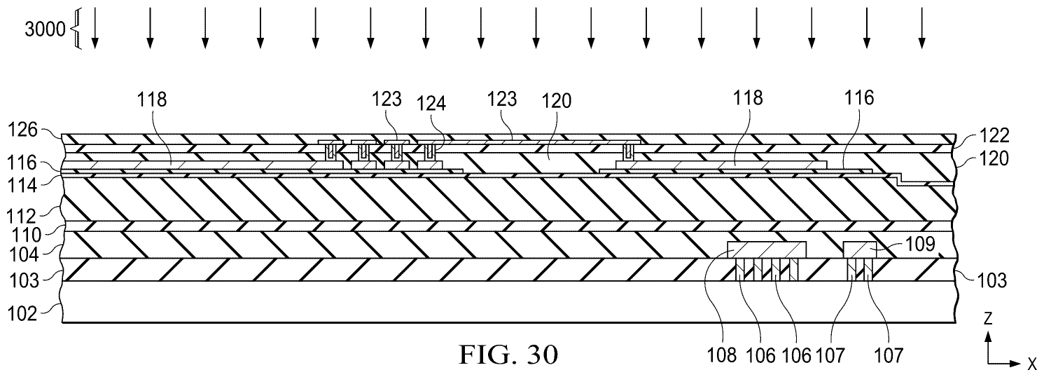

At 258 in FIG. 2, a top sub layer (e.g. the dielectric sublayer 126 in FIG. 1 above) of the dielectric seal structure 121 is formed to enclose the TFR layer 123 in a hermetic seal structure. FIG. 30 shows one example, in which the dielectric sublayer 126 implemented as an upper SiON dielectric seal layer (e.g., a fourth SiON layer) is formed by a deposition process 3000 of any suitable stoichiometry and thickness (e.g., approximately 0.1 μm) over the patterned features of the TFR layer 123 and the top surface of the dielectric layer 122.

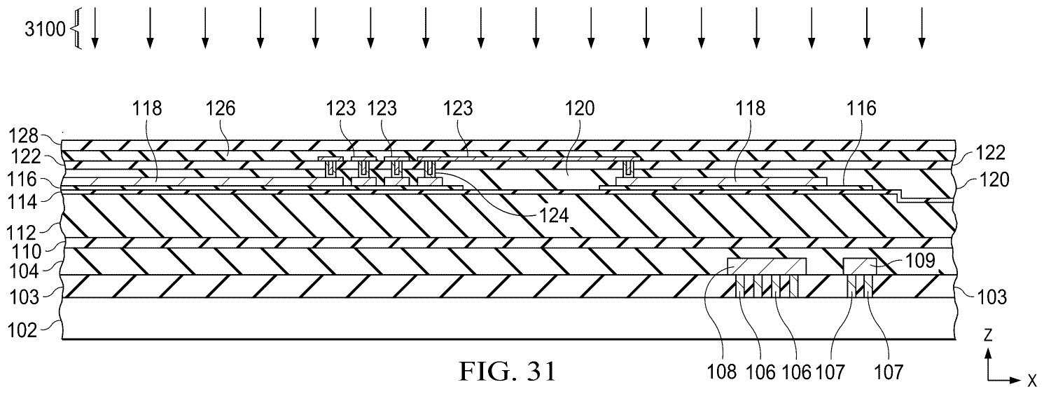

At 260-264 in FIG. 2, the method 200 in one example includes forming a protective overcoat (PO) bilayer including further silicon dioxide or other dielectric layer over the seal structure 121 and a dielectric layer over the silicon dioxide. At 260, the silicon dielectric layer 128 is deposited over the dielectric seal structure 121. FIG. 31 shows one example, in which a PECVD deposition process 3100 is performed that deposits a silicon dioxide layer, e.g. TEOS oxide, as dielectric layer 128, having any suitable stoichiometry and thickness (e.g., approximately 1.0 μm) over (e.g., on and directly contacting) the top surface of the dielectric sublayer 126.

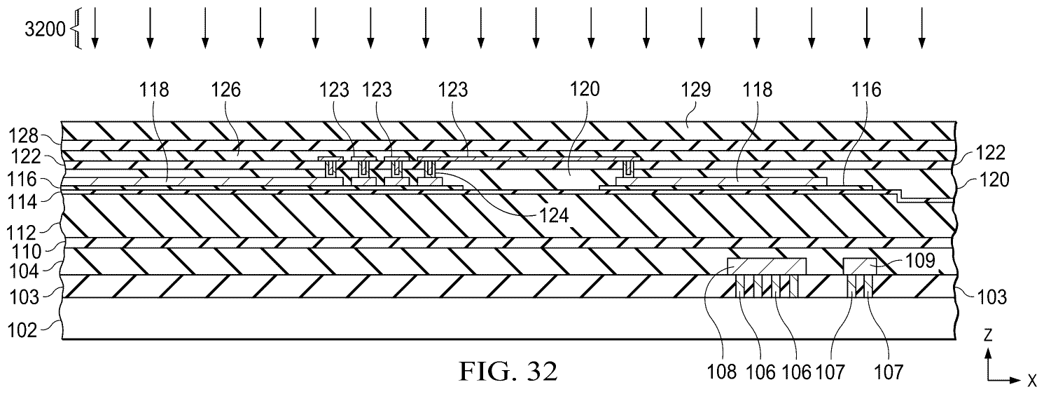

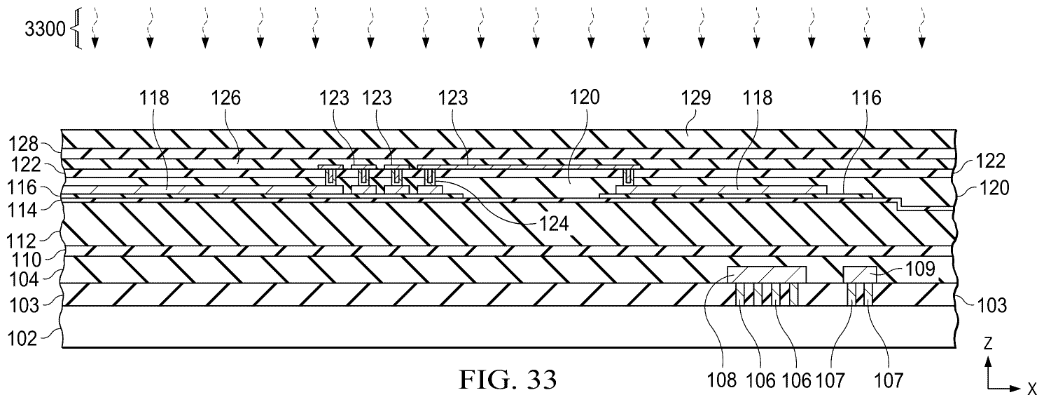

At 262 in FIG. 2, an upper protective overcoat layer is formed. FIG. 32 shows one example, in which a deposition process 3200 is performed that deposits the dielectric layer 129, e.g., a fifth silicon oxynitride layer, of any suitable stoichiometry and thickness (e.g., approximately 2.8 μm) over (e.g., on and directly contacting) the top surface of the dielectric layer 128. At 264 in FIG. 2, the method 200 in one example further includes annealing. FIG. 33 shows one example, in which a thermal process 3300 is performed that anneals the structure, for example using N₂ at approximately 400-450 degrees C., to drive underlying metals into more tensile state to help limit the wafer bow due to all the compressive dielectric depositions.

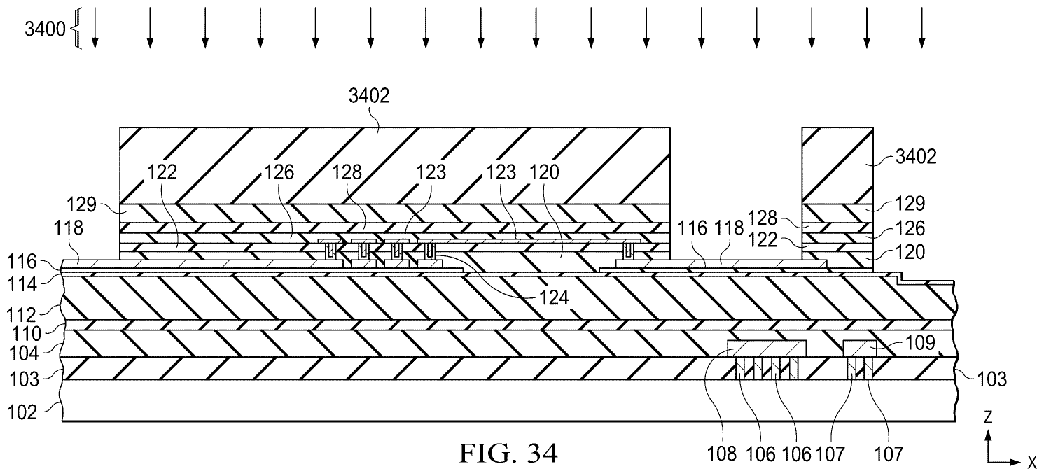

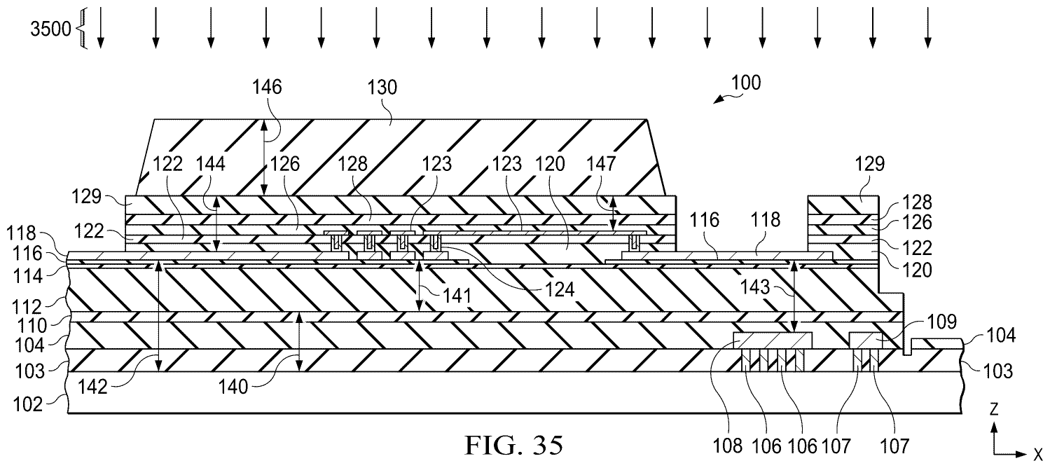

The method 200 continues at 266 and 268 in FIG. 2 with etch processing. At 266, a protective overcoat patterned etch is performed. FIG. 34 shows one example, in which an etch process 3400 is performed using an etch mask 3402 to remove exposed portions of the layers 120, 122, 126, 128, and 129 to expose portions of the top surfaces of the resistor terminals of the pad metal layer 118 to facilitate subsequent electrical connection by bond wires. The etch process 3400 in one example etches away some of the scribe region on the right side of FIG. 34 to facilitate subsequent plateau etching of that region (e.g., at 268 in FIG. 2). At 268 in FIG. 2, a plateau etch is performed using an etch mask (not shown) to etch through laterally peripheral portions of each prospective die area of a processed wafer. FIG. 35 shows one example, in which the wafer has been processed by a plateau etching process 3500 along the right-hand side scribe line region at the peripheral edge of the illustrated prospective die portion of the wafer. At 269 in FIG. 2, the polyimide layer 130 over (e.g., on and directly contacting) the dielectric layer 129 above the TFR layer 123 as further shown in FIG. 35, for example using a dispense or screening process (e.g., to a thickness 146 of approximately 8-10 μm) over portions of the protective overcoat stack to create a stress barrier to mitigate mechanical stress at the surface of the dielectric layer 129 of the protective overcoat stack and also to reduce the electric fields in the eventual epoxy mold compound (EMC) over the die. As shown in FIG. 35, the polyimide layer 190 has gaps that exposes the top sides of the resistor terminals of the pad metal layer 118.

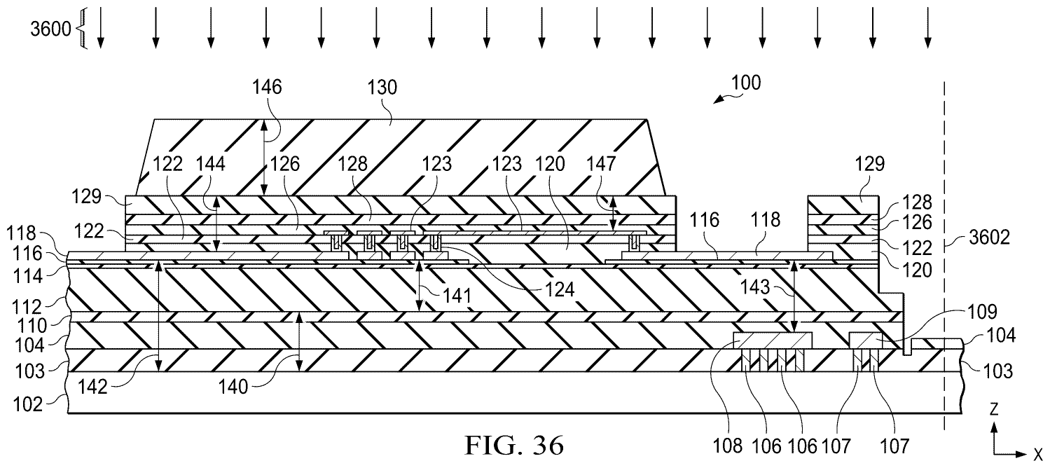

At 270 and FIG. 2, the method 200 continues with die separation to separate individual semiconductor dies from the processed wafer. FIG. 36 shows one example, in which a die separation or singulation process 3600 is performed that separates the illustrated die along a cut line 3602 in the scribe line region at the periphery of each prospective die area of the processed wafer. The method 200 continues at 272 in FIG. 2 with die attach processing (e.g., to attach the die to the die attach pad or other starting lead frame such as package structure 150 to as shown in FIG. 1), as well as electrical connection (e.g., by forming the bond wires 161, 162, and 163 in FIG. 1), molding processing and parentheses e.g., to form the molded package structure 150 in FIG. 1), and any required package separation processing (e.g., to separate fabricated packaged electronic devices from a processed lead frame panel array of rows and columns of integrated circuits 100).

Described examples advantageously provide a solution to mitigate or avoid the use of discrete resistors for high voltage sensing applications or other voltage isolation applications, with the voltage divider resistors R1 and R2 of the illustrated example being provided on-chip by integration into the integrated circuit 100 on a dedicated voltage divider die of a multichip module implementation, or by incorporation into a single die of an integrated circuit device. Described examples provide silicon dioxide or other dielectric layers as a high voltage insulator between the TFR layer 123 and the underlying substrate or semiconductor layer 102, covering the TFR layer 123 with high electrical breakdown strength dielectrics and encapsulating the die within an MCM with mold compound of the package structure 150 (FIG. 1) that mitigates or prevents air breakdown over the TFR layer 123. In addition, the thin film resistors 123 are formed above the resistor terminal metal features of the second metallization structure level (e.g., terminals 131-133 of the pad metal layer 118) to provide sufficient dielectric spacing between the resistors 123 and the underlying semiconductor layer 102 to facilitate high-voltage operation without voltage breakdown. Moreover, the illustrated examples provide a hermetic dielectric seal structure 121 (e.g., FIG. 1) to mitigate corrosion or other degradation of the thin-film resistors 123 to provide enhanced sensing circuit performance for high voltage isolation in a compact integrated form together with high precision thin film sensing resistors. Described examples provide a compact solution that avoids mounting discrete resistors on a host system circuit board to form a voltage divider on a PCB and instead fully integrates the resistor network onto a significantly smaller area of silicon that enables the voltage divider and the sensing circuits to co-exist within a single small outline integrated circuit (e.g., SOIC) using direct eye integration or combination with multiple semiconductor dies in a multichip module (MCM) package with significantly reduced system board area and integrated circuit device cost.

Modifications are possible in the described examples, and other implementations are possible, within the scope of the claims.

What is claimed is:

1. An integrated circuit, comprising:
a multilevel metallization structure over a semiconductor layer, the multilevel metallization structure having a dielectric layer;
a pad metal layer on the dielectric layer and including first and second resistor terminals; and
a resistor connected between the first and second resistor terminals and including a resistive path in a resistive layer over the pad metal layer, a first location of the resistive path connected to the first resistor terminal by a first vertical interconnect, and a second location of the resistive path connected to the second resistor terminal by a second vertical interconnect.

2. The integrated circuit of claim 1, wherein the resistive layer is located on a first sublayer of a dielectric seal structure, and a second sublayer of the dielectric seal structure is on the resistive layer.

3. The integrated circuit of claim 2, wherein the first and second sublayers comprise silicon oxynitride.

4. The integrated circuit of claim 1, wherein the resistive layer comprises silicon and chromium.

5. The integrated circuit of claim 1, wherein the resistive layer comprises silicon, chromium and carbon.

6. The integrated circuit of claim 1, wherein the pad metal layer is at least 15 μm above a top surface of the semiconductor layer.

7. The integrated circuit of claim 1, wherein the dielectric layer is a silicon nitride layer on a silicon oxynitride layer.

8. The integrated circuit of claim 1, wherein there is a gap in the dielectric layer between the first and second resistor terminals.

9. The integrated circuit of claim 8, wherein the resistive layer is spaced apart from the semiconductor layer by a spacing distance that is greater than or equal to 10.0 μm.

10. The integrated circuit of claim 1, further comprising:
a protective overcoat over the resistive layer, the protective overcoat including an inorganic dielectric layer; and
an organic dielectric layer over the protective overcoat, openings in the organic dielectric layer and the protective overcoat exposing the first and second resistor terminals.

11. The integrated circuit of claim 10, wherein the resistive layer is spaced apart from the semiconductor layer by a spacing distance that is greater than or equal to 10 μm.

12. The integrated circuit of claim 1, further comprising a first bond wire connected to the first resistor terminal, and a second bond wire connected to the second resistor terminal.

13. The integrated circuit of claim 12, further comprising a molded package structure that encloses the multilevel metallization structure and the bond wires.

14. The integrated circuit of claim 1, wherein the resistor includes a serpentine structure between the first and second locations.

15. The integrated circuit of claim 14, wherein the resistor includes a resistive layer turnaround that connects ends of adjacent linear segments, and a pad metal layer turnaround connected to the resistive layer turnaround by vertical interconnects.

16. An integrated circuit, comprising:
a semiconductor layer; and
a multilevel metallization structure over the semiconductor layer, the multilevel metallization structure having a film resistor, a first resistor terminal, a second resistor terminal that is spaced apart from the first resistor terminal, and a dielectric seal structure that encloses the film resistor, wherein the film resistor is located on a first sublayer of the dielectric seal structure, and a second sublayer of the dielectric seal structure is on the film resistor.

17. The integrated circuit of claim 16, wherein the first sublayer of the dielectric seal structure includes silicon oxynitride, and the second sublayer of the dielectric seal structure includes silicon oxynitride.

18. A method of fabricating an electronic device, the method comprising:
forming a dielectric layer in a multilevel metallization structure over a semiconductor layer;
forming a pad metal layer on the dielectric layer and including first and second resistor terminals; and
forming a film resistor over the pad metal layer, a first location of the film resistor connected to the first resistor terminal by a first vertical interconnect, and a second location of the film resistor connected to the second resistor terminal by a second vertical interconnect.

19. The method of claim 18, further comprising enclosing the film resistor in a dielectric seal structure in the multilevel metallization structure.

20. The method of claim 19, wherein enclosing the film resistor includes:
forming a first silicon oxynitride layer over a silicon dioxide layer;
forming the film resistor over and contacting the first silicon oxynitride layer; and
forming a second silicon oxynitride layer over and contacting the film resistor.

21. The method of claim 19, further comprising forming a protective overcoat over the dielectric seal structure.
